(19) United States
(12) Patent Application Publication
(10) Pub. No.: US 2026/0282843 A1
(43) Pub. Date: Sep. 17, 2026

(54) SUBSTRATE PROCESSING METHOD AND SUBSTRATE PROCESSING APPARATUS

(71) Applicant: Tokyo Electron Limited, Tokyo (JP)

(72) Inventors: Susumu HAYAKAWA, Kikuchi-gun, Kumamoto (JP); Hideyuki INOUE, Kikuchi-gun, Kumamoto (JP)

(73) Assignee: Tokyo Electron Limited, Tokyo (JP)

(21) Appl. No.: 19/472,715

(22) PCT Filed: Mar. 27, 2024
(86) PCT No.: PCT/JP2024/012499

§ 371 Date: Oct. 6, 2025

(30) Foreign Application Priority Data
Apr. 7, 2023 (JP) 2023-062838

(51) Int. Cl. H10P 74/20; B23K 26/00; B23K 26/03; B23K 26/062; B23K 26/36; B23K 101/40; B24B 37/08; B24B 37/28; H10P 52/20; H10P 70/00; H10P 72/00; H10P 72/50; H10P 72/76

(52) U.S. Cl. CPC H10P 74/203; B23K 26/0093; B23K 26/03; B23K 26/0626; B23K 26/36; B24B 37/08; B24B 37/28; H10P 52/20; H10P 70/70; H10P 72/0428; H10P 72/50; H10P 72/7602; B23K 2101/40

(57) ABSTRACT

A substrate processing method includes preparing a substrate having a first main surface and a second main surface, each of the first and the second main surfaces having waviness, performing a laser processing of the first main surface, performing a grinding or polishing processing of the second main surface, and preforming a grinding or polishing processing of the first main surface in this order. The substrate processing method includes acquiring map data of the waviness of the first main surface before the laser processing; and setting a processing condition for a current laser processing based on, in addition to the map data of the waviness of the first main surface, required data of the substrate previously subjected to the laser processing of the first main surface, the grinding or polishing processing of the second main surface, and the grinding or polishing processing of the first main surface in this order.

### TECHNICAL FIELD

The various aspects and embodiments described herein pertain generally to a substrate processing method and a substrate processing apparatus.

### BACKGROUND

Patent Document 1 describes a processing method for a semiconductor wafer. In this processing method, a semiconductor wafer obtained by slicing a single crystal ingot is subjected to chamfering, lapping, etching, and mirror polishing processes.

### PRIOR ART DOCUMENT

Patent Document 1: Japanese Patent Laid-open Publication No. 2002-203823

### DISCLOSURE OF THE INVENTION

### Problems to be Solved by the Invention

Exemplary embodiments provide a technique that improves the flatness of a substrate.

### Means for Solving the Problems

In an exemplary embodiment, a substrate processing method includes preparing a substrate having a first main surface and a second main surface opposite to the first main surface, each of the first main surface and the second main surface having waviness, performing a laser processing of the first main surface of the substrate, performing a grinding or polishing processing of the second main surface, and preforming a grinding or polishing processing of the first main surface in this order. The substrate processing method includes acquiring map data of the waviness of the first main surface before the laser processing; and setting a processing condition for a current laser processing based on, in addition to the map data of the waviness of the first main surface acquired before the current laser processing, required data of the substrate previously subjected to the laser processing of the first main surface, the grinding or polishing processing of the second main surface, and the grinding or polishing processing of the first main surface in this order.

### EFFECT OF THE INVENTION

According to the exemplary embodiments, it is possible to improve the flatness of the substrate.

### BRIEF DESCRIPTION OF THE DRAWINGS

FIG. 1 is a flowchart showing a substrate processing method according to an exemplary embodiment.

FIG. 2 is a cross sectional view illustrating an example of a process S101.

FIG. 3 is a cross sectional view illustrating an example of a process S103.

FIG. 4 is a cross sectional view illustrating an example of a process S104.

FIG. 5 is a cross sectional view illustrating an example of a process S106.

FIG. 6A and FIG. 6B are cross sectional views illustrating an example of a process S108 and a process S110, respectively.

FIG. 7 is a plan view illustrating a substrate processing apparatus according to the exemplary embodiment.

FIG. 8 is a diagram illustrating example components of a control circuit as functional blocks.

FIG. 9 is a plan view illustrating an example movement of a radiation point in a processing area.

FIG. 10 is a cross sectional view illustrating an example of local recesses.

FIG. 11 is a plan view illustrating a modification example of the movement of the radiation point in the processing area.

FIG. 12 is a diagram showing an example power density of the radiation point.

FIG. 13A is a diagram showing an example of map data of waviness of a first main surface obtained before a laser processing, FIG. 13B is a diagram showing an example of map data of a processing amount in the laser processing, and FIG. 13C is a diagram showing an example of the waviness of the first main surface obtained after a grinding processing.

### DETAILED DESCRIPTION

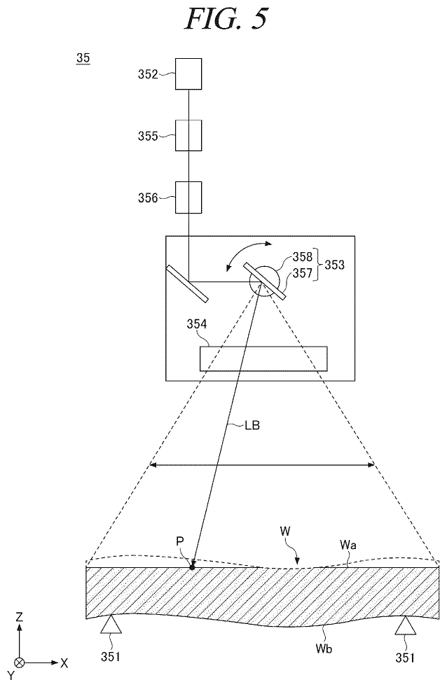

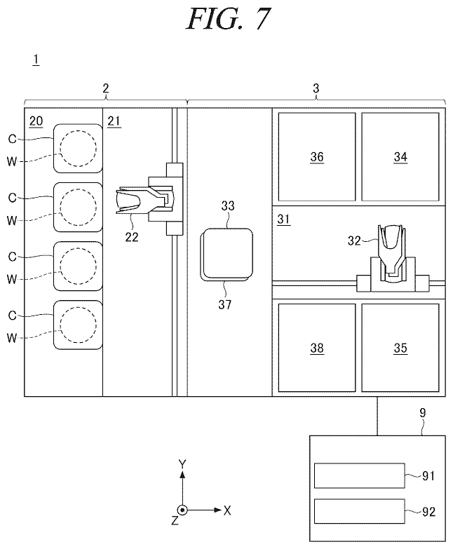

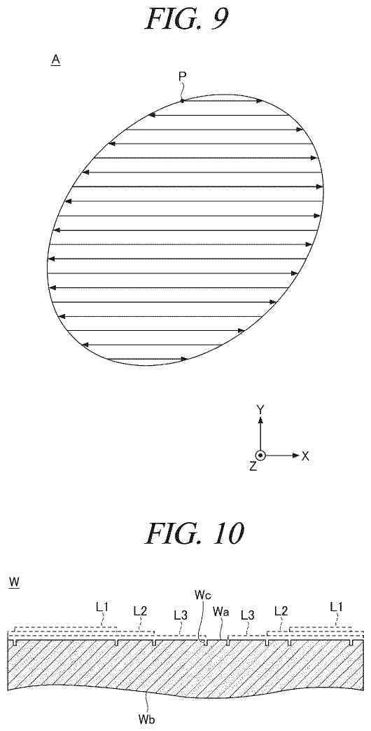

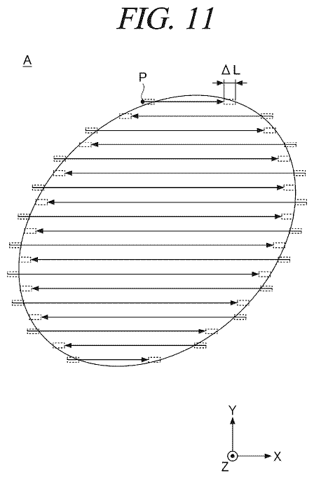

Hereinafter, embodiments of the present disclosure will be explained with reference to the accompanying drawings. In the various drawings, same or corresponding parts will be assigned same reference numerals, and redundant descriptions thereof will be omitted. In FIG. 5, FIG. 7, FIG. 9, and FIG. 11, the X-axis, Y-axis, and Z-axis directions are mutually orthogonal directions. The X-axis and Y-axis directions are horizontal directions, and the Z-axis direction is a vertical direction.

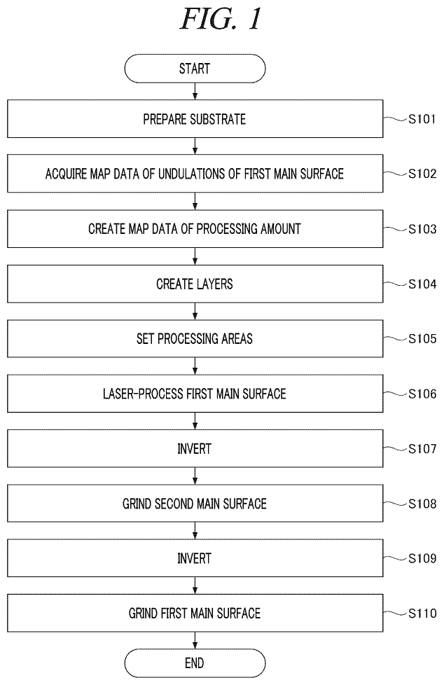

Referring to FIG. 1 to FIG. 6B, a substrate processing method according to an exemplary embodiment will be described. The substrate processing method includes, by way of example, processes S101 to S110, as shown in FIG. 1. The processes S101 to S110 are performed under a control of a control circuit. A polishing processing may be performed in place of a grinding processing.

The substrate processing method does not need to include all the processes S101 through S110 shown in FIG. 1. For example, since a plurality of substrates constituting one and the same lot are likely to have the same or similar waviness, the processes S102 to S105 may be performed on a single substrate. Processing conditions for one substrate may also be used as laser processing conditions for the other substrates. The plurality of (e.g., 25 sheets of) substrates constituting the same lot may be simultaneously cut from a single crystal ingot and accommodated in the same cassette.

The substrate processing method may further include a process not shown. Such a process may include, by way of example, cleaning or etching of the substrate. The cleaning or etching of the substrate may be performed immediately after a laser processing (process S106) or immediately after a grinding processing (process S108 or S110), for example. Both cleaning and etching may be performed.

The etching of the substrate may be performed before map data of the waviness is acquired (process S102). By removing, through the etching, a damage layer generated when cutting the single crystal ingot, the measurement accuracy for the map data of the waviness can be improved. Furthermore, since the damage layer is no longer a problem, the cutting speed can be increased.

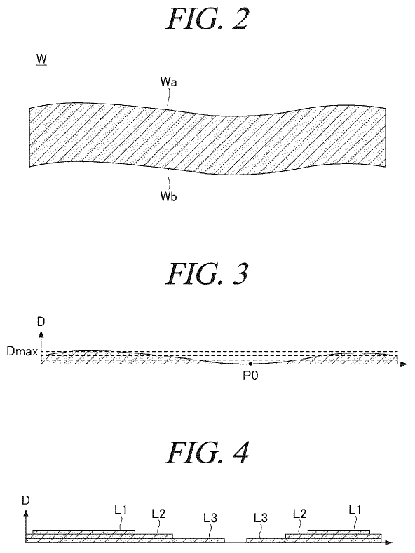

Below, the processing from the process S101 onwards will be explained. The process S101 involves preparing a substrate W (see FIG. 2). Preparing the substrate W includes, for example, carrying the substrate W into a substrate processing apparatus 1 to be described later. The substrate W is carried into the substrate processing apparatus 1 while being accommodated in a cassette C.

The substrate W is a silicon wafer or a compound semiconductor wafer. The compound semiconductor wafer may be, by way of example, a GaAs wafer, a SIC wafer, a GaN wafer, or an InP wafer, but not limited thereto. The substrate W is a bare wafer. The substrate W is of, for example, a circular plate shape. The substrate W may have a bevel at a periphery thereof.

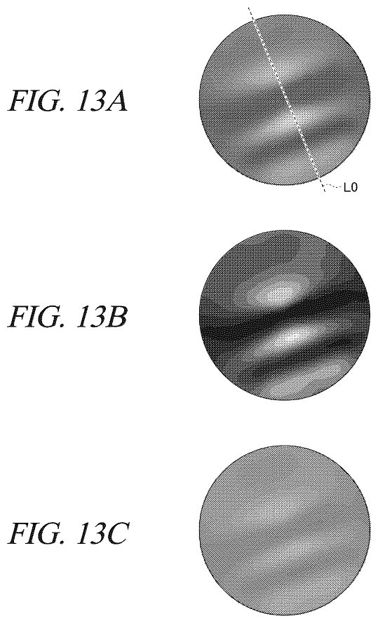

As shown in FIG. 2, the substrate W includes a first main surface Wa and a second main surface Wb opposite to the first main surface Wa. The substrate W has waviness on each of the first main surface Wa and the second main surface Wb. The waviness tends to be line-symmetrical with respect to a reference line LO extending in a cutting direction, as shown in FIG. 13A. In FIG. 13A to FIG. 13C, the height of the map data is expressed in grayscale. A greater height corresponds to a color closer to white from black.

The waviness on each of the first main surface Wa and the second main surface Wb are measured in advance by using a waviness measuring device. The waviness measuring device may be of either a contact or a non-contact type. A commercially available three-dimensional measurer, such as SBW-330 manufactured by Kobelco Electronics Co., Ltd., may be used as the waviness measuring device. The waviness is expressed as a height from a reference plane. The reference plane is planar. By way of example, the reference plane is a plane obtained by approximating a central surface between the first main surface Wa and the second main surface Wb using a least squares method. Alternatively, however, the reference plane may be a crystal plane represented by a required Miller index, or a plane inclined by a required off-angle from that crystal plane.

The process S102 includes acquiring map data of the waviness of the first main surface Wa. The map data of the waviness may be acquired for both a top surface and a bottom surface of the substrate W, and the surface with a relatively small difference in the height of the waviness may be set as the first main surface Wa. The first main surface Wa may be a surface to be subjected to a laser processing.

The process S103 includes creating map data of a processing amount D, as shown in FIG. 3, based on the map data of the waviness acquired in the process S102. In FIG. 3, dashed lines represent contour lines. The processing amount D is primarily determined based on a height from a reference point PO in the map data of the waviness. The height of the reference point PO is the height of the first main surface Wa obtained by the laser processing. The reference point PO may be the lowest point in the map data of the waviness, or a point shifted downwards by a set amount from that lowest point.

As will be explained in detail later, the map data of the processing amount D may be created by using a model generated by machine learning.

The process S104 involves creating n (e.g., three) layers L1, L2, and L3 by dividing the map data of the processing amount D created in the process S103 according to the height, as shown in FIG. 4. Here, n denotes an integer equal to or greater than 2, and is not limited to 3.

Here, the value n is set based on a maximum value Dmax of the processing amount D and a processing amount per radiation of a laser beam. The processing amount per radiation is determined by a power density at a radiation point P. Further, the value n may also be set based on an upper limit of the surface roughness after the laser processing.

In the present exemplary embodiment, the n layers L1, L2, and L3 have the same thickness, but they may have different thicknesses. The thickness of each of the n layers L1, L2, and L3 is set appropriately depending on the power density of the radiation point P, an amount of overlap between the trajectories of adjacent radiation points P, and so forth. By way of example, the thickness may be, 0.1 μm to 1.0 μm.

The process S105 involves setting a processing area for each of the layers L1, L2, and L3 created in the process S104. In the present exemplary embodiment, the processing areas of the layers L1, L2, and L3 coincide with the layers L1, L2, and L3, respectively, but they do not have to coincide. By way of example, the processing area of the layer L3, which is the lowest layer in FIG. 4, may be extended so as to connect two separated layers L3.

The process S106 includes performing a laser processing on the first main surface Wa, as shown in FIG. 5. The laser processing is an ablation processing. At the radiation point P of a laser beam LB, the substrate W is locally removed by scattering after a local phase change from a solid state into a gas state, or by scattering while remaining in the solid state. Details of a laser processing device 35 will be elaborated.

The process S106 includes moving the radiation point P of the laser beam LB in the processing area of each of the layers L1, L2, and L3. The n layers L1, L2, L3 are removed in any required order. For example, the layer with a higher height (e.g., layer L1) is removed before the layer with a lower height (e.g., layer L2).

The process S106 involves moving the radiation point P throughout the entire processing area of the kth layer to be removed and then moving the radiation point P throughout the entire processing area of the (k+1)^{th} layer to be removed. Here, k is an integer between 1 and (n−1) inclusive. As a result, the layers L1, L2, and L3 are removed one by one.

According to the present exemplary embodiment, the radiation point P is moved in the processing area for each of the layers L1, L2, and L3. The n layers L1, L2, and L3 can be removed in a required order. Since each of the layers L1, L2, and L3 has a constant thickness, the power density of the radiation point P does not need to be changed in most of each processing area, and an output of a light source does not need to be changed, either. This simplifies a control of the laser processing.

As stated above, the n layers L1, L2, and L3 may have the same thickness. The power density of the radiation point P does not need to be changed for each of the layers L1, L2, and L3, and the output of the light source does not need to be changed, either. As a result, the control of the laser processing can be more simplified. However, taking into account such a factor as a gradient of the waviness, two or more of the n layers L1, L2, and L3 may have different thicknesses.

Further, although the radiation point P is moved in the processing area for each of the layers L1, L2, and L3 in the present exemplary embodiment, the technology of the present disclosure is not limited thereto. If the power density of the radiation point P is changed each time according to the position of the radiation point P while referring to the height of the map data of the processing amount D, it is not necessary to divide the map data of the processing amount D into the n layers.

The process S107 includes inverting the substrate W. To elaborate, the process S107 involves turning the substrate W upside down so that the first main surface Wa of the substrate W faces downwards and the second main surface Wb of the substrate W faces upwards.

The process S108 includes grinding the second main surface Wb while the first main surface Wa, which has been planarized by the laser processing, is attracted to an attraction surface 391a of a chuck 391. A processing tool 392 includes, for example, a grinding whetstone. By grinding the second main surface Wb parallel to the previously planarized first main surface Wa, the second main surface Wb can be planarized. Here, polishing may be performed instead of the grinding.

When the attraction surface 391a of the chuck 391 attracts the first main surface Wa in the state that the first main surface Wa has the waviness, the first main surface Wa is planarized, conforming to the attraction surface 391a. In this state, if the second main surface Wb is ground parallel to the first main surface Wa and the attraction of the substrate W is then released, not only does the first main surface Wa return to the state having the waviness, but the same waviness as the first main surface Wa may also appear on the second main surface Wb.

According to the present exemplary embodiment, the second main surface Wb can be planarized by grinding the second main surface Wb parallel to the first main surface Wa, which has previously been planarized by the laser processing. Furthermore, as compared to planarizing both surfaces of the substrate W with the laser beam, the waviness present on both surfaces of the substrate W can be removed in a shorter time. This is because the laser processing has a lower processing speed than the grinding processing.

The process S109 includes inverting the substrate W. To elaborate, the process S109 involves turning the substrate W upside down so that the first main surface Wa of the substrate W faces upwards and the second main surface Wb of the substrate W faces downwards.

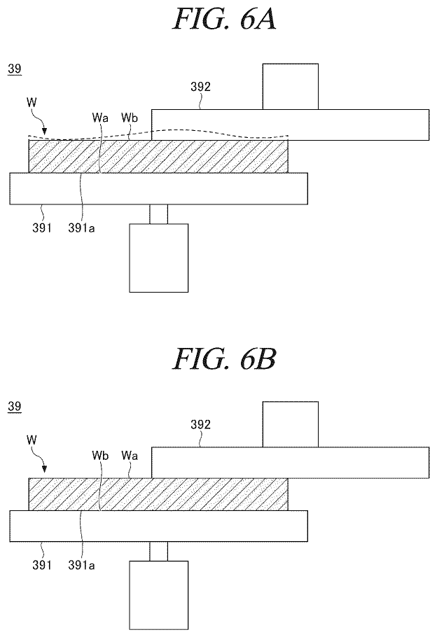

The process S110 involves performing a grinding processing on the first main surface Wa while attracting the second main surface Wb, which has been planarized by the grinding processing, on the attraction surface 391a of the chuck 391, as shown in FIG. 6B. This allows the processing quality of the first main surface Wa to be equivalent to the processing quality of the second main surface Wb. Because the first main surface Wa is completely planarized by the laser processing, the amount of grinding of the first main surface Wa may be less than the amount of grinding of the second main surface Wb. Here, the polishing processing may be performed instead of the grinding processing.

Now, referring to FIG. 7, the substrate processing apparatus 1 according to the exemplary embodiment will be described. The substrate processing apparatus 1 performs the processes S101 to S107 shown in FIG. 1. The processes S108 to S110 are performed outside the substrate processing apparatus 1. Further, the substrate processing apparatus 1 may be equipped with a grinding apparatus 39 shown in FIG. 6A and FIG. 6B, and may perform the processes S108 to S110. Furthermore, a polishing apparatus may be provided instead of the grinding apparatus 39.

The substrate processing apparatus 1 includes a carry-in/out station 2, a processing station 3, and a control circuit 9. The carry-in/out station 2 and the processing station 3 are arranged in this order from the negative X-axis side toward the positive X-axis side.

The carry-in/out station 2 includes a placement table 20, a second transfer section 21, and a second transfer device 22. Multiple cassettes C are placed on the placement table 20. Each cassette C accommodates a plurality of substrates W. The plurality of substrates W simultaneously cut from a single crystal ingot are accommodated in the same cassette C. The number of the cassettes C is not particularly limited.

The second transfer section 21 is adjacent to the placement table 20 and a transition device 33 of the processing station 3. The second transfer device 22 transfers substrates between the multiple devices adjacent to the second transfer section 21. The second transfer device 22 includes a transfer arm that holds the substrate W, and a driver that moves or rotates the transfer arm. The transfer arm is configured to be movable horizontally (in the X-axis and Y-axis directions) and vertically and pivotable around a vertical axis. A plurality of such transfer arms may be provided.

The processing station 3 includes a first transfer section 31, a first transfer device 32, a transition device 33, a waviness measuring device 34, a laser processing device 35, a cleaning device 36, an inverting device 37, and an alignment device 38. Here, the layout and the number of the devices constituting the processing station 3 are not limited to those shown in FIG. 7.

The first transfer section 31 is adjacent to the transition device 33, the waviness measuring device 34, the laser processing device 35, the cleaning device 36, the inverting device 37, and the alignment device 38. The first transfer device 32 transfers substrates between the multiple devices adjacent to the first transfer section 31. The first transfer device 32 has a transfer arm that holds the substrate W, and a driver that moves or rotates the transfer arm. The transfer arm is configured to be movable horizontally (in the X-axis and Y-axis directions) and vertically and pivotable around a vertical axis. A plurality of such transfer arms may be provided.

The transition device 33 relays the substrate W between the second transfer device 22 of the carry-in/out station 2 and the first transfer device 32 of the processing station 3. The transition device 33 for relaying the substrate W from the second transfer device 22 to the first transfer device 32 and the transition device 33 for relaying the substrate W from the first transfer device 32 to the second transfer device 22 may be provided separately.

The waviness measuring device 34 measures the waviness of the first main surface Wa of the substrate W. The waviness measuring device 34 may also measure the waviness of the second main surface Wb of the substrate W. The waviness measuring device 34 transmits the measurement data to the control circuit 9. The control circuit 9 obtains map data of the waviness of the first main surface Wa from the waviness measuring device 34. In this exemplary embodiment, the waviness measuring device 34 is provided inside the substrate processing apparatus 1, but it may be provided outside the substrate processing apparatus 1.

In the present exemplary embodiment, although the waviness measuring device 34 measures the waviness of the first main surface Wa of the substrate W before the laser processing, it may measure the waviness of the first main surface Wa of the substrate W after the laser processing. Further, the waviness measuring device 34 may measure the waviness of the first main surface Wa of the substrate W after the grinding or polishing processing.

The laser processing device 35 performs a laser processing of the first main surface Wa of the substrate W. The laser processing device 35 moves the radiation point P in the processing area for each of the layers L1, L2, and L3, for example. The n layers L1, L2, and L3 can be removed in a required order. By performing the laser processing of the first main surface Wa, the waviness of the first main surface Wa can be reduced.

The inverting device 37 turns the substrate W upside down. Like the transition device 33, the inverting device 37 may relay the substrate W between the first transfer device 32 and the second transfer device 22. The inverting device 37 and the transition device 33 may be stacked vertically.

The alignment device 38 detect a notch of the substrate W while rotating the substrate W, allowing the notch of the substrate W to be oriented in a required direction. The notch indicates the crystal orientation of the substrate W. The alignment device 38 may detect an orientation flat instead of the notch.

The control circuit 9 is, for example, a computer, and includes a processor 91 such as a CPU (Central Processing Unit) and a storage 92 such as a memory. The storage 92 stores a program that controls the various processes performed in the substrate processing apparatus 1. The control circuit 9 controls the operation of the substrate processing apparatus 1 by causing the processor 91 to execute the program stored in the storage 92. Lower-level control circuits that control the operations of the individual devices constituting the substrate processing apparatus 1 may be provided, and a higher-level control circuit that controls the multiple lower-level control circuits may be provided. In this case, the control circuit 9 may be composed of the lower-level control circuits and the higher-level control circuit.

The control circuit 9 includes an electronic circuit such as a CPU, a FPGA (Field Programmable Gate Array), or an ASIC (Application Specific Integrated Circuit), and performs various control operations described in the present disclosure by executing instruction codes stored in a memory or by being designed as a dedicated circuit for special purposes.

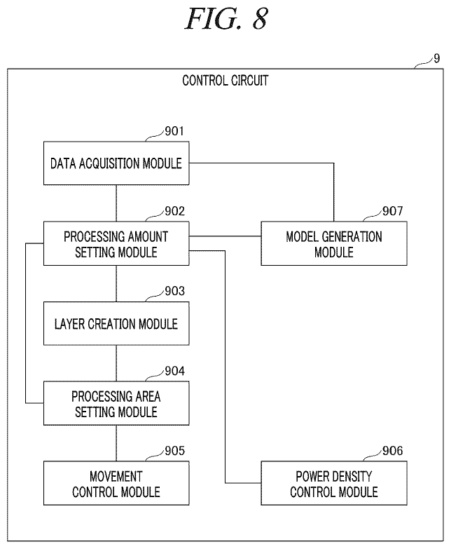

As shown in FIG. 8, the control circuit 9 includes, by way of example, a data acquisition module 901, a processing amount setting module 902, a layer creation module 903, a processing area setting module 904, a movement control module 905, a power density control module 906, and a model generation module 907. The data acquisition module 901 acquires the map data of the waviness of the first main surface Wa of the substrate W. The processing amount setting module 902 creates the map data of the processing amount D for the laser processing based on the map data of the waviness acquired by the data acquisition module 901. The layer creation module 903 creates the n layers L1, L2, and L3 by dividing the map data of the processing amount D, which has been created by the processing amount setting module 902, according to the heights. The processing area setting module 904 sets the processing area for each of the layers L1, L2, and L3 created by the layer creation module 903. The movement control module 905 controls the movement of the radiation point P in the processing area for each layer L1, L2, and L3. The power density control module 906 controls the power density (W/cm²) of the radiation point P. The model generation module 907 generates a model for use in creating the map data of the processing amount D, as will be described in detail later.

The individual functional blocks shown in FIG. 8 are conceptual and may not necessarily be physically configured exactly the same as shown in FIG. 8. All or a part of the functional blocks may be functionally or physically dispersed or combined on a unit. All or a part of processing functions performed in the respective functional blocks may be implemented by a program executed by the CPU or implemented by hardware through a wired logic.

Now, the operation of the substrate processing apparatus 1 configured as described above will be explained. First, a non-illustrated transfer device carries the substrate W into the substrate processing apparatus 1. This initiates preparation of the substrate W (process S101). The substrate W is placed on the placement table 20 while being accommodated in the cassette C. Next, the second transfer device 22 takes out the substrate W from the cassette C on the placement table 20, and transfers it to the transition device 33. Subsequently, the first transfer device 32 of the processing station 3 takes out the substrate W from the transition device 33 and transfers it to the alignment device 38.

Then, the alignment device 38 detects the notch of the substrate W while rotating the substrate W, allowing the notch of the substrate W to be oriented in a required direction. Thereafter, the first transfer device 32 takes out the substrate W from the alignment device 38 and transfers it to the waviness measuring device 34.

Next, the waviness measuring device 34 measures the waviness of the first main surface Wa of the substrate W. The waviness measuring device 34 transmits the measurement data to the control circuit 9. The data acquisition module 901 acquires the map data of the waviness of the first main surface Wa (process S102). Then, the processing amount setting module 902 creates the map data of the processing amount D for the laser processing based on the map data of the waviness (process S103). Thereafter, the layer creation module 903 creates the n layers L1, L2, and L3 by dividing the map data of the processing amount D according to the heights (process S104). Then, the processing area setting module 904 sets the processing area for each of the layers L1, L2, and L3 (process S105).

Next, the first transfer device 32 takes out the substrate W from the waviness measuring device 34 and transfers it to the laser processing device 35. Here, the processes S102 to S105 need to be performed before the laser processing of the first main surface Wa (process S106) is begun. The processes S102 to S105 may be performed after the first transfer device 32 takes out the substrate W from the waviness measuring device 34.

Subsequently, the laser processing device 35 laser-processes the first main surface Wa (process S106). The movement control module 905 controls the movement of the radiation point P in the processing area for each of the layers L1, L2, and L3. After the laser processing of the first main surface Wa, the first transfer device 32 takes out the substrate W from the laser processing device 35 and transfers it to the cleaning device 36.

Then, the cleaning device 36 cleans the first main surface Wa of the substrate W. Thereafter, the first transfer device 32 takes out the substrate W from the cleaning device 36 and transfers it to the inverting device 37. Then, the inverting device 37 turns the substrate W upside down (process S107). Next, the second transfer device 22 takes out the substrate W from the inverting device 37 and places it in the cassette C on the placement table 20. Finally, the non-illustrated transfer device takes out the substrate W accommodated in the cassette C from the substrate processing apparatus 1.

Now, referring back to FIG. 5, an example of the laser processing device 35 will be explained. The laser processing device 35 includes a substrate holder 351, a light source 352, and a galvano scanner 353. Further, the laser processing device 35 may also be equipped with an fθ lens 354, a homogenizer 355, and an aperture 356.

The substrate holder 351 holds the substrate W. By way of example, the substrate holder 351 holds the substrate W horizontally from below with the first main surface Wa of the substrate W facing upwards. The substrate holder 351 does not attract the substrate W, but just holds the substrate W in a natural state where no external forces other than gravity and its resistance act on it. Alternatively, the substrate holder 351 may attract the substrate W. The substrate holder 351 may be a vacuum chuck or an electrostatic chuck.

The light source 352 emits the laser beam LB. If the substrate W is a silicon wafer, the laser beam LB is, for example, UV light. At the radiation point P of the laser beam LB, the substrate W undergoes a local phase change from a solid state into a gas state to be scattered, or scattered in the solid state, thereby locally etching the substrate W. The laser beam LB may be radiated to be focused on the top surface of the substrate W. In the present exemplary embodiment, the radiation point P is a focal point where the power density is the highest, but it may not be the focal point.

The light source 352 is, for example, a pulsed laser. A radiation time per pulse is, for example, 30 nsec or less. If the radiation time per pulse is 30 nsec or less, the laser beam LB with a high power density can be radiated to the substrate W in a short period of time, suppressing overheating of the substrate W. Accordingly, thermal degradation of the substrate W can be suppressed, and state of a discoloration layer, for example, can be suppressed. It is desirable that the radiation time per pulse is 10 psec or less. If the radiation time per pulse is 10 psec or less, thermal degradation of the substrate W due to the heat can be suppressed even if multiple radiation points P are formed at the same location.

The galvano scanner 353 is disposed above the substrate W held by the substrate holder 351, for example. The galvano scanner 353 allows the radiation point P of the laser beam LB to be moved on the top surface of the substrate W without moving the substrate holder 351. Even when the substrate holder 351 does not attract the substrate W, the position of the substrate W relative to the substrate holder 351 may not be shifted as long as the substrate holder 351 is not moved. Therefore, the position of the radiation point P can be controlled with high precision.

The galvano scanner 353 includes two pairs of galvano mirrors 357 and galvano motors 358 (only one pair is shown in FIG. 5). One galvano motor 358 rotates one galvano mirror 357 to displace the radiation point P in the X-axis direction. Another galvano motor 358 rotates another galvano mirror 357 to displace the radiation point P in the Y-axis direction.

The galvano scanner 353 is an example of a mover that moves the radiation point P. The mover may be configured to move the substrate holder 351 in the X-axis direction and the Y-axis direction, or may include a motor and a ball screw mechanism that converts a rotation motion of the motor into a linear motion of the substrate holder 351. Further, the mover may also be equipped with a mechanism configured to rotate the substrate holder 351 around a vertical axis.

The fθ lens 354 forms a focal plane perpendicular to the Z-axis direction. While the galvano scanner 353 is moving the position of the radiation point P in the X-axis direction or the Y-axis direction, the fθ lens 354 maintains the shape and the dimensions of the radiation point P on the top surface of the substrate W. In the present exemplary embodiment, the height of the radiation point P coincides with the height of the focal plane, but it does not have to coincide with the height of the focal plane and may be higher or lower than the height of the focal plane.

The homogenizer 355 converts a power density distribution of the laser beam LB from a Gaussian distribution to a top-hat distribution, homogenizing the power density. The aperture 356 modifies a cross sectional shape of the laser beam LB into a rectangle. The aperture 356 is a light-blocking film having a rectangular opening. This opening allows a portion of the laser beam LB having a uniform power density to pass therethrough. In this way, the rectangular radiation point P with the uniform power density can be formed by the homogenizer 355 and the aperture 356.

Now, an example of the movement of the radiation point P in the processing area A will be explained with reference to FIG. 9. In FIG. 9, arrows indicate a movement direction and a movement range of the radiation point P. The movement range is a range from a start point of the movement to an end point of the movement. Arrows in FIG. 11, which will be described later, have the same meaning. Here, it should be noted that the movement of the radiation point P is not limited to the examples shown in FIG. 9 and FIG. 11. By way of example, the radiation point P may be moved in a spiral shape.

As illustrated in FIG. 9, for example, the movement control module 905 repeatedly performs a control of moving the radiation point P in a first direction (e.g., the positive X-axis direction) and a control of moving the radiation point P in a second direction (e.g., the negative X-axis direction) opposite to the first direction. In addition, before and after changing the movement direction of the radiation point P between the first and second directions, the movement control module 905 performs a control of shifting the position of the radiation point P in a third direction (e.g., the negative Y-axis direction) perpendicular to the first and second directions.

A first trajectory of the radiation point P moving in the first direction and a second trajectory of the radiation point P moving in the second direction, which are adjacent to each other in the third direction, may partially overlap in the third direction. A pitch of the radiation point P in the third direction may be smaller than the size of the radiation point P in the third direction so that the first and second trajectories partially overlap in the third direction. By partially overlapping the first and second trajectories in the third direction, a processing mark formed along the movement direction of the radiation point P (the first or second direction) can be made thinner.

The movement control module 905 may perform a control of changing the movement direction of the radiation point P vertically or diagonally between the kth layer to be removed and the (k+1)^{th} layer to be removed. By way of example, the movement control module 905 may perform a control of changing the movement direction of the radiation point P vertically or diagonally between an odd-numbered layer to be removed and an even-numbered layer to be removed.

For example, when removing the odd-numbered layers L1 and L3, the movement control module 905 may repeat the control of moving the radiation point P in the first direction and the control of moving the radiation point P in the second direction. Further, when removing the odd-numbered layers L1 and L3, the movement control module 905 performs the control of shifting the position of the radiation point P in the third direction before and after changing the movement direction of the radiation point P between the first and second directions.

Meanwhile, when removing the even-numbered layer L2, the movement control module 905 repeats the control of moving the radiation point P in the third direction and a control of moving the radiation point P in a fourth direction (e.g., the positive Y-axis direction), which is opposite to the third direction. Further, when removing the even-numbered layer L2, the movement control module 905 performs the control of shifting the position of the radiation point P in the first or second direction before and after changing the movement direction of the radiation point P between the third and fourth directions.

As described above, the movement control module 905 performs the control of changing the movement direction of the radiation point P vertically or diagonally (vertically in this exemplary embodiment) between the kth layer to be removed and the (k+1)^{th} layer to be removed. This allows the processing mark formed along the movement direction of the radiation point P to become thinner. As a result, the surface roughness of the first main surface Wa after the laser processing can be reduced.

The processing area A is set for each of the layers L1, L2, and L3. A periphery of the processing area A coincides with a periphery of the corresponding one of the layers L1, L2, and L3. The start point at which the movement of the radiation point P is begun and the end point at which the movement of the radiation point P is ended are set on the periphery of the processing area A, as shown in FIG. 9, for example.

The inventors of the present application have found out that when the start point and the end point are set on the periphery of the processing area A as shown in FIG. 9, recesses Wc are formed locally along the periphery of the processing area A as shown in FIG. 10. This is presumed to result from unintentional lengthening of the radiation time of the laser beam LB at the start point and the end point.

If the second main surface Wb is ground parallel to the first main surface Wa in the state where the recesses Wc are formed on the first main surface Wa and the attraction of the substrate W is then released, local recesses similar to those on the first main surface Wa may be formed on the second main surface Wb.

Here, as shown in FIG. 11, the movement control module 905 performs a control of shifting at least one of the start point and the end point (both in FIG. 11) from the periphery of the processing area A. A shifting direction may be directed toward the inside of the processing area A or toward the outside of the processing area A. A shifting distance AL is set in advance through, for example, an experiment or the like. By shifting the position of at least one of the start point and the end point from the periphery of the processing area A, it is possible to suppress the recesses Wc from being formed locally along the periphery of the processing area A, thereby improving the processing quality of the laser processing.

In the present exemplary embodiment, the movement control module 905 shifts the positions of the start point and the end point from the periphery of the processing area A in both cases of moving the radiation point P in the first direction and moving the radiation point P in the second direction. However, the technology of the present disclosure is not limited thereto. The start point and the end point may be set in a zigzag pattern along the periphery of the processing area A, that is, so as to approach and move away from the periphery of the processing area A repeatedly along the periphery of the processing area A.

By way of example, if the movement control module 905 shifts the positions of both the start point and the end point from the periphery of the processing area A when moving the radiation point P in the first direction, the movement control module 95 does not have to shift the start point and the end point from the periphery of the processing area A when moving the radiation point P in the second direction. Alternatively, in both cases of moving the radiation point P in the first direction and moving the radiation point P in the second direction, the movement control module 905 may shift the position of only the start point from the periphery of the processing area A, or may shift the position of only the end point from the periphery of the processing area A.

As stated above, the start point and the end point may be set in the zigzag pattern along the periphery of the processing area A, that is, so as to approach and move away from the periphery of the processing area A repeatedly along the periphery of the processing area A. As a result, the formation of the recesses Wc may be suppressed. This effect is particularly conspicuous when the first and second trajectories adjacent in the third direction partially overlap in the third direction.

When the first trajectory and the second trajectory adjacent to each other in the third direction partially overlap in the third direction, the start point of the first trajectory and the end point of the second trajectory are positioned apart from each other so as not to overlap. Likewise, when the first trajectory and the second trajectory adjacent to each other in the third direction partially overlap in the third direction, the end point of the first trajectory and the start point of the second trajectory are positioned apart from each other so as not to overlap. As a result, the formation of the recesses Wc may be suppressed.

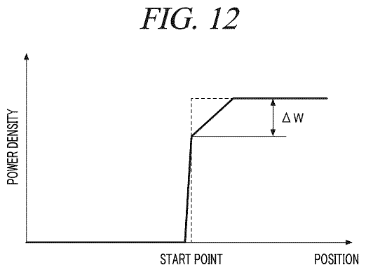

Alternatively, as shown in FIG. 12, the power density control module 906 may perform a control of reducing the power density of the radiation point P at the periphery of the processing area A as compared to the power density at the center of the processing area A. A decrement AW of the power density is set in advance through an experiment or the like. The power density of the radiation point P is controlled by adjusting the output of the light source 352, for example. By reducing the power density of the radiation point P at the periphery of the processing area A as compared to the power density at the center of the processing area A, it is possible to suppress the local formation of the recesses Wc along the periphery of the processing area A, thereby improving the processing quality of the laser processing.

Furthermore, the control shown in FIG. 11 and the control shown in FIG. 12 may be performed in combination. In addition, the control shown in FIG. 11 and the control shown in FIG. 12 may also be applicable to a case where the map data of the processing amount D is not divided into the n layers L1, L2, and L3. In this case as well, it is possible to suppress the local formation of the recesses Wc along the periphery of the processing area A, thereby improving the processing quality of the laser processing.

Now, referring to FIG. 13A to FIG. 13C, an example of three map data of the substrate W after being subjected to the laser processing of the first main surface Wa, the grinding processing of the second main surface Wb, and the grinding processing of the first main surface Wa in this order as shown in FIG. 1 will be explained. FIG. 13A presents the map data of the waviness of the first main surface Wa acquired before the laser processing. FIG. 13B shows the map data of the processing amount D in the laser processing. FIG. 13C provides the map data of the waviness of the first main surface Wa obtained after the grinding processing. In FIG. 13A to FIG. 13C, the height of the map data is expressed in grayscale. A greater height corresponds to a color closer to white from black.

The inventors of the present application have created the map data of the processing amount D so that the waviness of the first main surface Wa is completely eliminated by the laser processing, and have performed the laser processing of the first main surface Wa according to that map data. However, they have found out that in some cases the waviness of the first main surface Wa remain after the grinding processing without being completely eliminated. This is presumed to result from unintended deformation of the substrate W that has occurred in the laser processing or the grinding processing. As mentioned above, the polishing processing may be performed instead of the grinding processing.

Therefore, the processing amount setting module 902 may create the map data of the processing amount D for the current laser processing based on, in addition to the map data of the waviness of the first main surface Wa obtained before the current laser processing, required data of a substrate W previously subjected to the laser processing of a first main surface Wa, the grinding or polishing processing of a second main surface Wb, and the grinding or polishing processing of the first main surface Wa in this order.

The required data may include, for example, n(A) map data of waviness of the first main surface Wa obtained before the laser processing, (B) map data of a processing amount D in the laser processing, and (C) data of the waviness of the first main surface Wa obtained after the grinding or polishing processing.

(C) The data of the waviness of the first main surface Wa obtained after the grinding or polishing processing is map data in the present exemplary embodiment, but it may be simple height difference data. The height difference of the waviness after the grinding or polishing processing is used as scoring data for the map data of the processing amount. The smaller the height difference of the waviness after the grinding or polishing processing is, the better the score would be.

According to the present exemplary embodiment, by using the required data as well as the map data of the waviness of the first main surface Wa acquired before the current laser processing, the map data of the processing amount D in the current laser processing can be appropriately corrected. As a result, the height difference of the waviness of the first main surface Wa acquired after the current grinding or polishing processing can be reduced.

For example, regression analysis or the like may be performed to absorb an error caused by an unintended deformation presumed to be generated in the past laser processing, grinding processing, or polishing processing to correct the map data of the processing amount D in the current laser processing. By feeding back the past data to the current processing conditions, the flatness of the substrate W can be improved.

The processing amount setting module 902 may input the map data of the waviness of the first main surface Wa, which is obtained prior to the current laser processing, into a model trained by machine learning using the required data as training data, thereby outputting the map data of the processing amount D for the current laser processing so that the height difference of the waviness after the current grinding or polishing processing becomes equal to or less than a set value. By using the previously machine-trained model, the map data of the processing amount D can be appropriately corrected regardless of the user's level of skill, i.e., without relying on the user's intuition.

The data input into the machine-trained model may include (E) map data of the waviness of the first main surface Wa to be obtained after the current grinding processing or polishing processing as well as (D) the map data of the waviness of the first main surface Wa obtained before the current laser processing. The data to be input into the model may include, instead of (E), (F) the height difference of the waviness of the first main surface Wa to be obtained after the current grinding or polishing processing.

The model may be used by being read out from a storage in which it has been stored in advance, or may be generated by the model generation module 907. The model generation module 907 uses the required data as training data and generates the model through supervised learning using a known machine learning algorithm such as a convolutional neural network (CNN).

Further, the processing amount setting module 902 is an example of a processing parameter setting module. The processing parameter setting module sets the current laser processing conditions based on the previously acquired required data in addition to the map data of the waviness of the first main surface Wa obtained before the current laser processing. The laser processing conditions may include at least one selected from, for example, the map data of the processing amount D, the number of the layers L1, L2, and L3, the thickness of each of the layers L1, L2, and L3, the shifting amount AL shown in FIG. 11, and the decrement 4W shown in FIG. 12.

So far, the exemplary embodiment of the substrate processing method and the substrate processing apparatus according to the present disclosure have been described. However, the present disclosure is not limited to the above-described exemplary embodiment and the like. Various changes, modifications, substitutions, additions, deletions and combinations may be made within the scope of the claims, which are all incorporated within a technical scope of the present disclosure.

This application claims priority to Japanese Patent Application No. 2023-062838, filed on Apr. 7, 2023, which application is hereby incorporated by reference in their entirety.

### EXPLANATION OF CODES

LB: Laser beam
P: Radiation point
W: Substrate
Wa: First main surface
Wb: Second main surface

1. A substrate processing method, comprising:
preparing a substrate having a first main surface and a second main surface opposite to the first main surface, each of the first main surface and the second main surface having waviness;
acquiring map data of the waviness of the first main surface before laser processing;
setting a processing condition for a current laser processing based on, in addition to the map data of the waviness of the first main surface acquired before the current laser processing, required data of the substrate previously subjected to the laser processing of the first main surface, grinding or polishing processing of the second main surface, and grinding or polishing processing of the first main surface; then
performing the laser processing of the first main surface of the substrate; then
performing the grinding or polishing processing of the second main surface; and then
preforming the grinding or polishing processing of the first main surface.

2. The substrate processing method of claim 1,
wherein the required data includes map data of the waviness of the first main surface acquired before the laser processing, and map data of a processing amount in the laser processing, and map data of the waviness of the first main surface acquired after the grinding or polishing processing, and
the processing condition includes map data of a processing amount.

3. A substrate processing method, comprising:
preparing a substrate having a first main surface and a second main surface opposite to the first main surface, each of the first main surface and the second main surface having waviness;
acquiring map data of the waviness of the first main surface before laser processing;
outputting, by a computer, map data of a processing amount in a current laser processing by inputting the map data of the waviness of the first main surface acquired before the current laser processing into a model trained by machine learning using, as training data, required data of the substrate previously subjected to the laser processing of the first main surface, grinding or polishing processing of the second main surface, and grinding or polishing processing of the first main surface;
performing the laser processing of the first main surface; then
performing the grinding or polishing processing of the second main surface; and then
performing the grinding or polishing processing of the first main surface,
wherein the required data includes map data of the waviness of the first main surface acquired before the laser processing, and map data of a processing amount in the laser processing, and map data of the waviness of the first main surface acquired after the grinding or polishing processing of the second main surface and the grinding or polishing processing of the first main surface.

4. The substrate processing method of claim 3, wherein the laser processing includes:
creating n (n is an integer equal to or greater than 2) layers by dividing the map data of the processing amount according to heights thereof;
setting a processing area for each layer; and
moving a radiation point of a laser beam in the processing area for each layer.

5. The substrate processing method of claim 4, wherein the laser processing includes:
changing a movement direction of the radiation point vertically or diagonally between a k^{th} (k is an integer between 1 and (n−1) inclusive) layer to be removed and a (k+1)^{th} layer to be removed.

6. The substrate processing method of claim 4,
wherein the n layers have the same thickness.

7. The substrate processing method of claim 4, wherein the laser processing includes at least one of:
shifting, from a periphery of the processing area, a position of at least one of a start point at which the moving of the radiation point is begun and an end point at which the moving of the radiation point is ended; and
reducing a power density of the radiation point at the periphery of the processing area as compared to a power density at a center of the processing area.

8. The substrate processing method of claim 7, wherein the laser processing includes:
repeatedly moving the radiation point in a first direction and in a second direction opposite to the first direction in the processing area, and shifting a position of the radiation point in a third direction perpendicular to the first direction and the second direction before and after changing a movement direction of the radiation point between the first direction and the second direction; and
shifting, from the periphery of the processing area, a position of at least one of the start point at which the moving of the radiation point in the first direction is begun and the end point at which the moving of the radiation point in the first direction is ended.

9. The substrate processing method of claim 8,
wherein the start point and the end point are arranged so as to approach and move away from the periphery of the processing area repeatedly along the periphery of the processing area.

10. The substrate processing method of claim 9,
wherein a trajectory of the radiation point moving in the first direction and a trajectory of the radiation point moving in the second direction, which are adjacent to each other in the third direction, partially overlap in the third direction.

11. A substrate processing apparatus, comprising:
a transfer device including a transfer arm, the transfer device being for transferring a substrate having a first main surface and a second main surface opposite to the first main surface, each of the first main surface and the second main surface having waviness;
a laser processing device for performing laser processing of the first main surface before performing a grinding or polishing processing of the second main surface and the first main surface; and
a control circuit configured to control the laser processing device,
wherein the control circuit performs:
acquiring map data of the waviness of the first main surface before the laser processing; and
setting a processing condition for a current laser processing based on, in addition to the map data of the waviness of the first main surface acquired before the current laser processing, required data of the substrate previously subjected to the laser processing of the first main surface, the grinding or polishing processing of the second main surface, and the grinding or polishing processing of the first main surface in this order.

12. The substrate processing apparatus of claim 11,
wherein the required data includes map data of the waviness of the first main surface acquired before the laser processing, and map data of a processing amount in the laser processing, and map data of the waviness of the first main surface acquired after the grinding or polishing processing, and
the processing condition includes map data of a processing amount.

13. A substrate processing apparatus, comprising:
a transfer device including a transfer arm, the transfer device being for transferring a substrate having a first main surface and a second main surface opposite to the first main surface, each of the first main surface and the second main surface having waviness;
a laser processing device for performing a laser processing of the first main surface before performing a grinding or polishing processing of the second main surface and the first main surface; and
a control circuit configured to control the laser processing device,
wherein the control circuit performs:
acquiring map data of the waviness of the first main surface before the laser processing; and
outputting map data of a processing amount in a current laser processing by inputting the map data of the waviness of the first main surface acquired before the current laser processing into a model trained by machine learning using, as training data, required data of the substrate previously subjected to the laser processing of the first main surface, the grinding or polishing processing of the second main surface, and the grinding or polishing processing of the first main surface in this order,
the required data includes map data of the waviness of the first main surface acquired before the laser processing, and map data of a processing amount in the laser processing, and map data of the waviness of the first main surface acquired after the grinding or polishing processing.

14. The substrate processing apparatus of claim 13,
wherein the control circuit performs creating n (n is an integer equal to or greater than 2) layers by dividing the map data of the processing amount according to heights thereof, setting a processing area for each layer and moving a radiation point of a laser beam of the laser processing device in the processing area for each layer.

15. The substrate processing apparatus of claim 14,
wherein the control circuit controls the laser processing device to perform changing a movement direction of the radiation point vertically or diagonally between a k^{th} (k is an integer between 1 and (n−1) inclusive) layer to be removed and a (k+1)^{th} layer to be removed.

16. The substrate processing apparatus of claim 14,
wherein the n layers have the same thickness.

17. The substrate processing apparatus of claim 14,
wherein the control circuit controls the laser processing device to perform at least one of:
shifting, from a periphery of the processing area, a position of at least one of a start point at which the moving of the radiation point is begun and an end point at which the moving of the radiation point is ended; and
reducing a power density of the radiation point at the periphery of the processing area as compared to a power density at a center of the processing area.

18. The substrate processing apparatus of claim 17,
wherein the control circuit controls the laser processing device to repeatedly perform moving the radiation point in a first direction and moving the radiation point in a second direction opposite to the first direction in the processing area, and performs shifting a position of the radiation point in a third direction perpendicular to the first direction and the second direction before and after changing a movement direction of the radiation point between the first direction and the second direction, and
shifting, from the periphery of the processing area, a position of at least one of a start point at which the moving of the radiation point in the first direction is begun and an end point at which the moving of the radiation point in the first direction is ended.

19. The substrate processing apparatus of claim 18,
wherein the start point and the end point are arranged so as to approach and move away from the periphery of the processing area repeatedly along the periphery of the processing area.

20. The substrate processing apparatus of claim 19,
wherein a trajectory of the radiation point moving in the first direction and a trajectory of the radiation point moving in the second direction, which are adjacent to each other in the third direction, partially overlap in the third direction.
